(19) United States
(12) Patent Application Publication
(10) Pub. No.: US 2008/0164060 A1
(43) Pub. Date: Jul. 10, 2008

(54) Electrical-Cable Shielding

(75) Inventor: Gregory Neil Burland, London (GB)

Correspondence Address: DAVIS BUJOLD & Daniels, P.L.L.C., 112 PLEASANT STREET, CONCORD, NH, 03301, US

(73) Assignee: ICORE INTERNATIONAL LIMITED, Berkshire (GB)

(21) Appl. No.: 11/994,149

(22) PCT Filed: Jun. 29, 2006
(86) PCT No.: PCT/GB2006/002392

§ 371 Date: Dec. 28, 2007

(30) Foreign Application Priority Data
Jun. 29, 2005 (GB) 051 3136.2

(51) Int. Cl. H05K 9/00

(52) U.S. Cl. 174/393

(57) ABSTRACT

A bundle of electrical cables (20) are shielded from electromagnetic interference by an elongate tape (1) wrapped widthwise round the bundle with its longitudinal edges (8,11) overlapping one another. The tape (1) includes a woven mesh (2) of bare-metal strands (5) sandwiched between outer and inner layers (4,3) of sheet-plastics, the weave being a narrow-fabric weave having warp strands (5) running longitudinally of the tape (1) and a single unbroken weft-strand (6). The mesh (2) is bare on the outside along one longitudinal margin (11) and also on the inside along the other longitudinal margin (8) for direct electrical contact between them within the overlap in establishing closed electrical circuits encircling the cable-bundle throughout the length of the tape (1). The margin (11) of the mesh (2) innermost in the wrap may instead be insulated, merely adding insignificant capacitance into the otherwise purely-resistive encircling circuits.

This is a national stage completion of PCT/GB2006/002392 filed Jun. 29, 2006 which claims priority from British Application Serial No. 0513136.2 filed Jun. 29, 2005.

### FIELD OF THE INVENTION

This invention relates to the shielding of electrical cables, and is concerned particularly with methods of electromagnetically shielding a bundle of electrical cables, and a flexible tape for use in such shielding.

### SUMMARY OF THE INVENTION

According to one aspect of the present invention there is provided a method of electromagnetically shielding a bundle of electrical cables wherein an elongate, flexible tape that extends lengthwise of the bundle is wrapped widthwise round the bundle with the longitudinal margins of the tape overlapping one another, the tape comprising a mesh of electrically-conductive strands with some of those strands running longitudinally of the tape, and the tape is retained wrapped round the bundle as aforesaid with the mesh providing closed electrical-circuit encirclement of the bundle via the overlap.

According to another aspect of the invention there is provided a flexible tape for extending lengthwise of a bundle of electrical cables and wrapping widthwise round the bundle for electromagnetic shielding of the bundle with the longitudinal margins of the tape overlapping one another, the tape comprising a mesh of electrically-conductive strands with some of those strands running longitudinally of the tape, and means for retaining the tape wrapped round the bundle as aforesaid with the mesh providing closed electrical-circuit encirclement of the bundle via the overlap.

The mesh of the method and tape of the invention may be of woven electrically-conductive strands with the warp of the weave running longitudinally of the tape. In this case, the weave may be a narrow-fabric weave, and may have a single unbroken weft strand.

The electrically-conductive strands may be individual wire-filaments or a plurality of wire-filaments twisted together, and the wire-filaments, which may be of nickel-coated copper, are preferably bare so that good electrical contact is established between all of them in common in the mesh.

The woven mesh of the method and tape of the invention may be covered by electrically-insulating material apart from along the longitudinal margins where there is to be overlap. In particular, the electrically-insulating material may be in the form of a plastics sheet that is secured to one of the two faces of the mesh for insulating the mesh electrically from the bundle of cables. Furthermore, the mesh may be backed on its other face by another plastics sheet for affording the tape resistance to physical damage resulting, for example, from abrasion. The sheet or sheets may be secured to the mesh by stitching.

Fabric fastening elements of the form sold under the Registered Trade Mark VELCRO, may be used for retention of the tape wrapped round the bundle.

### BRIEF DESCRIPTION OF THE DRAWINGS

A method of electromagnetically-shielding a bundle of electrical cables, and a flexible tape for such use, all in accordance with the present invention will now be described, by way of example, with reference to the accompanying drawings, in which:

FIG. 1 is a representative cross-section of the electromagnetically-shielding tape according to the invention;

FIG. 2 is illustrative of a plan view of the tape of FIG. 1;

FIG. 3 is illustrative schematically of the weave of a wire-mesh that forms part of the tape of FIGS. 1 and 2;

FIG. 4 is a cross-sectional view of a bundle of electrical cables wrapped in the tape of FIGS. 1 and 2 for electromagnetic shielding according to the method of the invention;

FIG. 5 is illustrative to an enlarged scale of a portion of the overlap between longitudinal margins of the tape of FIGS. 1 and 2 shown in FIG. 4; and

FIG. 6 is illustrative of a modification of the tape of FIGS. 1 and 2.

### DETAILED DESCRIPTION OF THE INVENTION

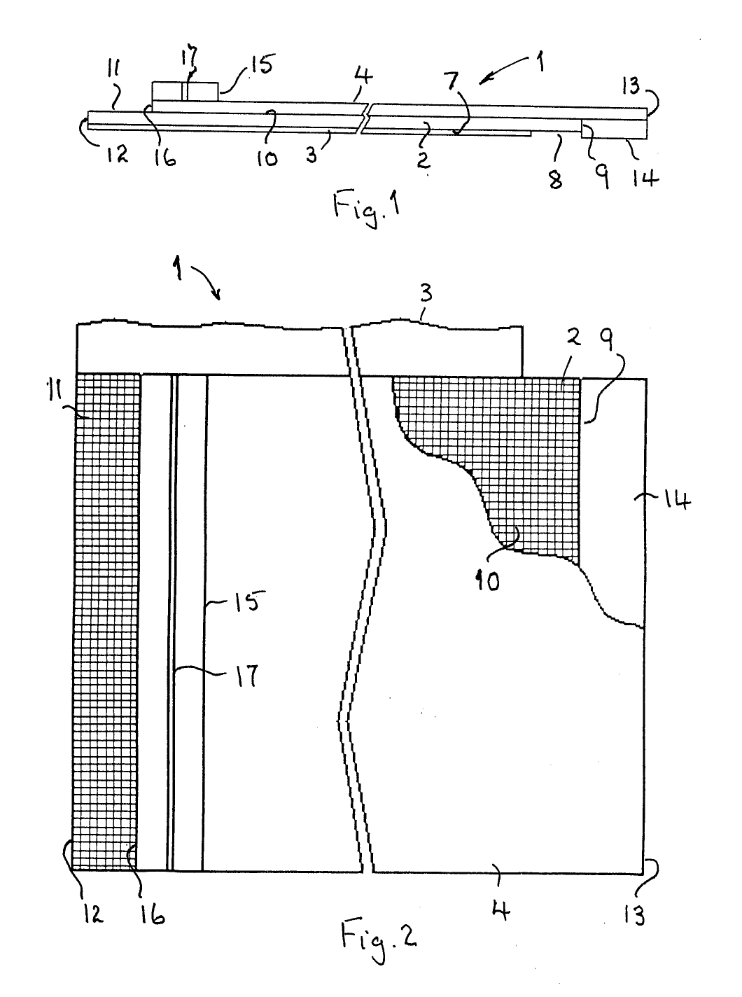

Referring to FIGS. 1 and 2, the shielding tape 1 is of a three-layered, light-weight construction including a woven mesh 2 of bare metal-wire strands (for example, in a twill weave). The mesh 2 is sandwiched between inner and outer electrically-insulating layers 3 and 4 respectively. The layers 3 and 4 are formed by strips of plastics sheet (the thicknesses of the layers 3 and 4 and the mesh 2 are exaggerated in the drawings). More particularly, the inner layer 3 is, for example, of polytetrafluoroethylene (PTFE) or polyvinyl chloride (PVC), and the outer layer 4 is of a hard-wearing plastics material, for example, a ketone-based resin such as polyetheretherketone (PEEK), for providing physical strength with resistance to abrasion.

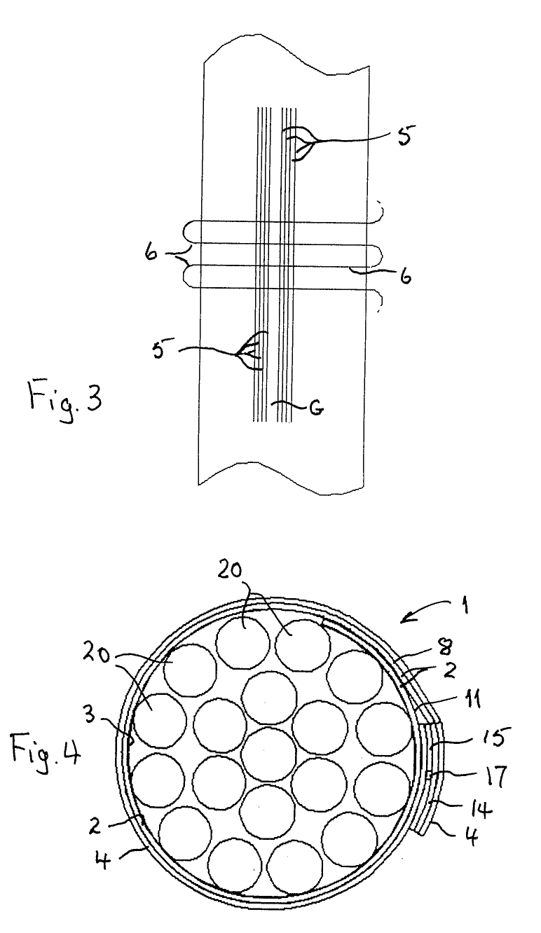

As indicated schematically by FIG. 3, the warp of the woven mesh 2 is formed by fine wire-strands 5 that run lengthwise of the tape 1, whereas the weft is formed by a fine wire-strand 6 running back and forth without break, in a narrow-fabric weave with the warp strands 5. The strands 5 and 6 are, for example, single wire-filaments or twisted pairs, of nickel-coated copper wire, and the strands 5 are fine enough that a group (in the case illustrated, of four) of them are drawn together through the dent-space of the loom in the weaving process; the gap G between the adjacent groups, resulting from the dents (and shown exaggerated in FIG. 3), is small enough that it does not materially affect the shielding provided. The weft strand 6 passes successively over one group of warp strands 5 and under the next in the weave.

The inner layer 3 is of a width to cover the inside face 7 of the woven mesh 2 apart from throughout a longitudinal marginal strip 8 of the face 7 at one longitudinal edge 9 of the bare mesh 2. The outer layer 4 correspondingly covers the outside face 10 of the mesh 2 apart from throughout a longitudinal marginal strip 11 of the face 10 at the other longitudinal edge 12 of the mesh 2. An edge 13 of the layer 4 lies beyond the edge 9 of the mesh 2 to carry a strip 14 of upstanding fibers that abuts the edge 9.

The strip 14 forms in conjunction with a second strip 15 of upstanding fibres, a pair of interengaging elements of a selectively-disengageable fabric-fastening of the kind, such as that sold under the Registered Trade Mark VELCRO, in which hook-ended fibres of one element engage with upstanding loop-ended fibers of a second element; in this case, for example, the element 14 has the loop-ended fibers and the strip 15 has the hook-ended fibers. The strip 15, which is supported along the opposite edge 16 of the layer 4, has a central, red-colored line 17 running throughout its length.

The mesh 2 together with the layers 3 and 4 and the strips 14 and 15 are retained in assembly with one another by stitching. By way of alternative, retention may be by bonding, and the strips 14 and 15 may be encapsulated into the plastic layer 4.

The tape 1 is used for electromagnetic shielding of a bundle of cables as will now be described principally with reference to FIG. 4.

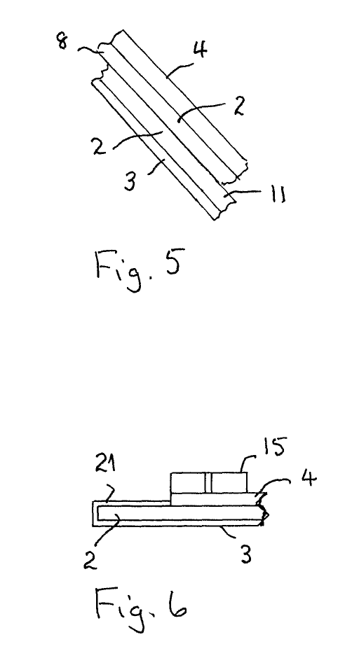

Referring to FIG. 4, the tape 1 is deployed running lengthwise of the bundle of electrical cables 20 with the inner layer 3 abutting the cables 20 of the bundle. The tape 1 is now wrapped widthwise round the bundle by folding its longitudinal margins round the bundle as indicated generally by arrows A in FIG. 1. Wrapping of the tape 1 round the bundle is carried through to bring the bare strip 8 of the mesh 2 over the bare strip 11 into an overlapping relationship with it as illustrated to a very enlarged scale in FIG. 5, and to engage the element 14 with the element 15; this overlap and engagement are established throughout the full length of the tape 1. Sufficiency of the area of engagement between the element 14 and the element 15 at each position throughout the length of the tape 1, so as to ensure that the tape 1 is correctly wrapped and secured, is confirmed if the red line 17 cannot be observed anywhere along that length; the red line 17 can be omitted and in these circumstances correct wrapping is confirmed if there is edge-to-edge alignment between the elements 14 and 15.

When the tape 1 is correctly wrapped, the strips 8 and 11 of the woven mesh 2 are in hard abutment with one another so as to ensure that there is good electrical contact between them and that optimum shielding is provided. With such contact, there is complete closed-circuit encirclement of the bundle, and low-resistance connection of that circuit with the weft strand 6 and each warp strand 5. The strands 5 and 6 are clamped into couplings (not shown) at either end of the bundle to ensure good ground connection. Moreover, the shortest possible path for discharge from and lengthwise of the bundle is provided by the warp strands 5 running longitudinally of the shielding tape 1; this is of especial importance for lightning protection, and is advantageous for maintaining a lightweight construction.

A modification of the tape 1 is illustrated in FIG. 6. More particularly in this regard, the layer 3 is extended round the edge 12 of the mesh 2 and covers the strip 11. When the modified tape 1 is wrapped round the cable-bundle, the extended portion 21 of the layer 3 enhances the integrity of the electrical insulation of the mesh 2 from the cable-bundle, but separates the strip 11 of the mesh 2 from its direct electrical contact with the strip 8. It has been found that this separation does not materially detract from the operation of the shielding tape, especially in relation to high-frequency interference. The closed-circuit encirclement of the bundle by the mesh 2 is now of low impedance with a small capacitative component instead of being solely resistive.

In some circumstances it may not be necessary or desired to provide insulation between the bare mesh 2 and the cables 20, so then a saving in cost and weight can be achieved simply by omitting the inner insulating layer 3 from the tape 1.

1-22. (canceled)

23. A method of electromagnetically shielding a bundle of electrical cables, the method comprising the steps of:
providing an elongate, flexible tape having longitudinal margins, the tape comprising a mesh of electrically-conductive strands with some of the electrically-conductive strands running longitudinally of the tape; extending the tape lengthwise of the bundle;
wrapping the tape widthwise round the bundle of electrical cables with the longitudinal margins of the tape overlapping one another; and
retaining the tape wrapped round the bundle as aforesaid with the mesh providing closed electrical-circuit encirclement of the bundle via the overlapping longitudinal margins of the tape.

24. The method according to claim 23, further comprising the step of using a mesh of woven electrically-conductive strands as the tape with the mesh having warp strands running longitudinally of the tape.

25. The method according to claim 24, further comprising the step of weaving the woven electrically-conductive strands with a narrow-fabric weave.

26. The method according to claim 24, further comprising the step of providing the woven electrically-conductive strands with a single unbroken weft strand.

27. The method according to claim 23, further comprising the steps of providing each longitudinal margin of the tape with electrically-conductive strands of the mesh, and retaining the tape wrapped round the bundle of electrical cables with the electrically-conductive strands of the longitudinal margins in mutual electrical contact by abutment with one another.

28. The method according to claim 23, further comprising the step of using an individual wire-filament as each electrically-conductive strand.

29. The method according to claim 23, further comprising the step of using a plurality of wire-filaments twisted together as each electrically-conductive strand.

30. The method according to claim 23, further comprising the step of using nickel-coated copper wire-filaments as the electrically-conductive strands comprise.

31. The method according to claims 23, further comprising the step of using bare metal, as the electrically-conductive strands of the mesh, to establish electrical contact between them all in common within the mesh.

32. The method according to claim 23, further comprising the step of sandwiching the mesh between electrically-insulating layers.

33. An electromagnetically-shielded bundle of electrical cables, wherein the bundle of electrical cables is shielded electromagnetically by a tape that extends lengthwise of the bundle of electrical cables, the tape having longitudinal margins and being wrapped widthwise round the bundle of electrical cables overlapping the longitudinal margins of the tape with one another, and the tape comprises a mesh of electrically-conductive strands with some of the electrically-conductive strands running longitudinally of the tape, and means for retaining the tape wrapped round the bundle as aforesaid with the mesh providing closed electrical-circuit encirclement of the bundle of electrical cables via the overlapping longitudinal margins of the tape.

34. The electromagnetically-shielded bundle of electrical cables, according to claim 33, comprising a mesh of woven electrically-conductive strands, the mesh having warp strands running longitudinally of the tape.

35. The electromagnetically-shielded bundle of electrical cables, according to claim 34, wherein the woven electrically-conductive strands are woven with a narrow-fabric weave.

36. The electromagnetically-shielded bundle of electrical cables, according to claim 34, wherein the woven electrically-conductive strands have a single unbroken weft strand.

37. The electromagnetically-shielded bundle of electrical cables, according to claim 33, wherein each longitudinal margin of the tape comprises electrically-conductive strands of the mesh, and the tape is retained wrapped round the bundle of electrical cables with the electrically-conductive strands of the longitudinal margins in mutual electrical contact by abutment with one another.

38. The electromagnetically-shielded bundle of electrical cables, according to claim 33, wherein each electrically-conductive strand is an individual wire-filament.

39. The electromagnetically-shielded bundle of electrical cables, according to claim 33, wherein each electrically-conductive strand comprises a plurality of wire-filaments twisted together.

40. The electromagnetically-shielded bundle of electrical cables, according to claim 33, wherein the electrically-conductive strands comprise nickel-coated copper wire-filaments.

41. The electromagnetically-shielded bundle of electrical cables, according to claim 33, wherein the electrically-conductive strands of the mesh are of bare metal to establish good electrical contact between them all in common within the mesh.

42. The electromagnetically-shielded bundle of electrical cables, according to claim 33, wherein the mesh is sandwiched between electrically-insulating layers.

43. The electromagnetically-shielded bundle of electrical cables, according to claim 33, wherein the means for retaining the tape wrapped round the bundle as aforesaid involves inter-engaging elements of a selectively-disengageable fabric-fastening.
